(19) United States
(12) Patent Application Publication
(10) Pub. No.: US 2026/0033121 A1
(43) Pub. Date: Jan. 29, 2026

(54) IMAGING DEVICE

(71) Applicant: Panasonic Intellectual Property Management Co., Ltd., Osaka (JP)

(72) Inventors: MORIO MITSUISHI, Kanagawa (JP); KENICHI AOYAMA, Tokyo (JP); HIROAKI IIJIMA, Nara (JP)

(21) Appl. No.: 19/347,782

(22) Filed: Oct. 2, 2025

Related U.S. Application Data
(63) Continuation of application No. PCT/JP2024/013627, filed on Apr. 2, 2024.

(30) Foreign Application Priority Data
Apr. 13, 2023 (JP) 2023-065803

(51) Int. Cl. H10K 39/32; H04N 25/618; H10F 39/00

(52) U.S. Cl. CPC H10K 39/32; H04N 25/618; H10F 39/802

(57) ABSTRACT

An imaging device includes pixels. Each of the pixels includes: a lower electrode; an upper electrode that is disposed to face the lower electrode; a photoelectric conversion layer that is positioned between the lower electrode and the upper electrode, includes a donor semiconductor material and an acceptor semiconductor material, and generates signal charges; a charge blocking layer that is positioned between the photoelectric conversion layer and the lower electrode; and a charge accumulation region that is electrically connected to the lower electrode and accumulates the signal charges. D/√S ≥ 0.07 is satisfied, where D is a thickness of the charge blocking layer, and S is an area of the lower electrode in plan view.

### BACKGROUND

### 1. Technical Field

The present disclosure relates to an imaging device.

### 2. Description of the Related Art

Stacked imaging devices have been proposed as metal oxide semiconductor (MOS) imaging devices. In the stacked imaging devices, a photoelectric conversion element including a photoelectric conversion layer is stacked above a semiconductor substrate, and charges generated by photoelectric conversion in the photoelectric conversion layer are collected by an electrode and accumulated in a charge accumulation region. For example, Japanese Unexamined Patent Application Publication No. 2007-311647 discloses a stacked imaging device that reads out charges accumulated in a charge accumulation region by using a charge coupled device (CCD) circuit or a complementary MOS (CMOS) circuit in a semiconductor substrate.

A photoelectric conversion element used in an imaging device may have a structure in which functional layers such as a photoelectric conversion layer that absorbs light and generates signal charges and a charge blocking layer that suppresses injection of charges from an electrode are stacked. For example, Japanese Unexamined Patent Application Publication No. 2012-94660 discloses an imaging device using a photoelectric conversion element having a structure in which a photoelectric conversion layer and a charge blocking layer are stacked.

### SUMMARY

Imaging devices are used in various environments. For example, regarding an imaging device for monitoring or for a vehicle, which is used in an imaging environment in which brightness changes considerably, it is required that the imaging device perform high-quality imaging irrespective of the imaging environment. That is, in the performance of an imaging device, it is important that the imaging device have a wide dynamic range. The dynamic range is determined by the saturation signal quantity and noise of the imaging device, and it is possible to realize a wide dynamic range by increasing the saturation signal quantity and/or by reducing the noise. Reduction of noise is also important in improving the quality of a captured image.

One non-limiting and exemplary embodiment provides an imaging device in which noise is reduced.

In one general aspect, the techniques disclosed here feature an imaging device including pixels. Each of the pixels includes: a first electrode; a second electrode that is disposed to face the first electrode; a photoelectric conversion layer that is positioned between the first electrode and the second electrode, includes a donor semiconductor material and an acceptor semiconductor material, and generates signal charges; an intermediate layer that is positioned between the photoelectric conversion layer and the first electrode; and a charge accumulation region that is electrically connected to the first electrode and accumulates the signal charges. D/√S ≥ 0.07 is satisfied, where D is a thickness of the intermediate layer, and S is an area of the first electrode in plan view.

With the present disclosure, it is possible to provide an imaging device in which noise is reduced.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic sectional view illustrating the configuration of a photoelectric conversion element according to an embodiment;

FIG. 2 is an exemplary energy band diagram of the photoelectric conversion element according to the embodiment;

FIG. 3 is a schematic sectional view illustrating the configuration of another photoelectric conversion element according to the embodiment;

FIG. 4 illustrates an example of the circuit configuration of an imaging device according to an embodiment;

FIG. 5 is a schematic sectional view illustrating the device structure of a pixel of the imaging device according to the embodiment;

FIG. 6 is a plan view illustrating an exemplary electrode layout in the imaging device;

FIG. 7 is a view for illustrating a case where an intermediate level is generated in a photoelectric conversion element having the energy band configuration illustrated in FIG. 2;

FIG. 8 is a graph illustrating examples of the distribution of the quantity of charges accumulated in a charge accumulation node;

FIG. 9 is a graph illustrating the relationship between D/√S and random noise in imaging devices according to Examples and Comparative Example; and

FIG. 10 is a graph illustrating the relationship between D/L and random noise in the imaging devices according to Examples and Comparative Example.

### DETAILED DESCRIPTIONS

### Underlying Knowledge Forming Basis of the Present Disclosure

The inventors have found that it is necessary to address the following problems in order to provide an imaging device in which noise is reduced.

To use a structure in which functional layers are stacked as a photoelectric conversion element of an imaging device, it is necessary to optimize the design of energy levels regarding materials included in the layers. For example, the energy level of a material included in a photoelectric conversion layer, which absorbs light and generates signal charges, greatly influences the sensitivity of the imaging device. The energy level of a material included in an intermediate layer, such as a charge blocking layer, between the photoelectric conversion layer and an electrode greatly influences the efficiency in extracting signal charges. In a photoelectric conversion element, an intermediate level tends to be generated in the vicinity of the interface between adjacent layers due to the influence of film-forming conditions and polarizing actions between materials. In particular, because the intermediate layer, which is positioned between the photoelectric conversion layer and an electrode, differs from the photoelectric conversion layer in the function in the photoelectric conversion element, it is difficult to predict generation of an intermediate level when designing the energy levels of materials. Due to the presence of an intermediate level, electrons are more easily excited to the intermediate level, and, in addition to signal charges generated by light, charges are more easily generated by thermal excitation even in a dark state. In an imaging device having pixels, charges are generated in a region in the vicinity of the interface between adjacent layers in each pixel, and the charges are captured by an electrode of a specific pixel with a certain probability and may generate noise.

The present disclosure has been made based on such findings and provides an imaging device in which is noise is reduced by reducing the influence of charges generated by thermal excitation.

### Overview of Present Disclosure

As an outline of an aspect of the present disclosure, examples of an imaging device according to the present disclosure will be described below.

An imaging device according to a first aspect of the present disclosure includes pixels. Each of the pixels includes: a first electrode; a second electrode that is disposed to face the first electrode; a photoelectric conversion layer that is positioned between the first electrode and the second electrode, includes a donor semiconductor material and an acceptor semiconductor material, and generates signal charges; an intermediate layer that is positioned between the photoelectric conversion layer and the first electrode; and a charge accumulation region that is electrically connected to the first electrode and accumulates the signal charges. D/√S ≥ 0.07 is satisfied, where D is a thickness of the intermediate layer, and S is an area of the first electrode in plan view.

With the configuration of the present aspect, it is possible to realize an imaging device in which noise is reduced.

To be specific, the quantity of charges generated by thermal excitation in the vicinity of the interface between the photoelectric conversion layer and the intermediate layer depends on the size of the interface. That is, as the area of the first electrode, which is related to the effective size of the interface, increases in plan view, the quantity of charges generated by thermal excitation increases. Because noise is proportional to the square root of the quantity of charges accumulated in the charge accumulation region, as charges generated by thermal excitation increase, noise also increases. On the other hand, as the thickness of the intermediate layer increases, it becomes difficult for charges generated by thermal excitation to be captured by the first electrode. In general, charges generated in the photoelectric conversion layer perform hopping conduction between materials included in the layers, and the charges are extracted to the first electrode and accumulated in the charge accumulation region. In this case, charges generated by thermal excitation perform hopping conduction at least over a distance corresponding to the thickness of the intermediate layer. As the distance over which charges perform hopping conduction increases, the probability that the charges become inactive increases, and contribution of charges generated by thermal excitation to noise decreases. Thus, noise can be reduced by adjusting the relationship between the thickness of the intermediate layer and the area of the first electrode, and sufficient noise reduction can be realized when D/√S ≥ 0.07 is satisfied, where D is the thickness of the intermediate layer and S is the area of the first electrode.

For example, an imaging device according to a second aspect of the present disclosure is the imaging device according to the first aspect, in which the thickness of the intermediate layer is greater than or equal to 10 nm.

Thus, for example, even when there is a large potential difference between the first electrode and the second electrode, it is possible to suppress leakage current from the first electrode to the photoelectric conversion layer.

For example, an imaging device according to a third aspect of the present disclosure is the imaging device according to the first or second aspect, in which the signal charges are holes, the intermediate layer includes a first semiconductor material, and a difference between an ionization potential of the first semiconductor material included in the intermediate layer and an ionization potential of the donor semiconductor material included in the photoelectric conversion layer is less than or equal to 1 eV.

For example, an imaging device according to a fourth aspect of the present disclosure is the imaging device according to the first or second aspect, in which the signal charge are electrons, the intermediate layer includes a first semiconductor material, and a difference between an electron affinity of the first semiconductor material included in the intermediate layer and an electron affinity of the acceptor semiconductor material included in the photoelectric conversion layer is less than or equal to 1 eV.

Thus, signal charges that are generated in the photoelectric conversion layer when the photoelectric conversion layer is irradiated with light can be easily transported from the photoelectric conversion layer to the first electrode through the intermediate layer, and the efficiency in extracting signal charges improves.

For example, an imaging device according to a fifth aspect of the present disclosure is the imaging device according to any one of the first to fourth aspects, in which each of the pixels further includes a charge blocking layer that is positioned between the second electrode and the photoelectric conversion layer.

Thus, it is possible to suppress leakage current from the second electrode to the photoelectric conversion layer.

For example, an imaging device according to a sixth aspect of the present disclosure is the imaging device according to the fifth aspect, in which a thickness of the charge blocking layer is greater than or equal to 5 nm.

Thus, for example, even if there is a large potential difference between first electrode and the second electrode, it is possible to suppress leakage current from the second electrode to the photoelectric conversion layer.

For example, an imaging device according to a seventh aspect of the present disclosure is the imaging device according to the fifth or sixth aspect, in which the signal charges are holes, the charge blocking layer includes a second semiconductor material, and a difference between an electron affinity of the second semiconductor material included in the charge blocking layer and an electron affinity of the acceptor semiconductor material included in the photoelectric conversion layer is less than or equal to 1 eV.

For example, an imaging device according to an eighth aspect of the present disclosure is the imaging device according to the fifth or sixth aspect, in which the signal charges are electrons, the charge blocking layer includes a second semiconductor material, and a difference between an ionization potential of the second semiconductor material included in the charge blocking layer and an ionization potential of the donor semiconductor material included in the photoelectric conversion layer is less than or equal to 1 eV.

Thus, charges whose polarity is opposite to that of signal charges, which are generated in the photoelectric conversion layer when the photoelectric conversion layer is irradiated with light, are more easily transported from the photoelectric conversion layer to the second electrode via the charge blocking layer, the charges whose polarity is opposite to that of signal charges generated in the photoelectric conversion layer do not easily recombine with the signal charges, and decrease of sensitivity is suppressed.

For example, an imaging device according to a ninth aspect of the present disclosure is the imaging device according to any one of the first to eighth aspects, in which D/√S ≥ 0.14 is satisfied.

Thus, it is possible to realize an imaging device in which noise is further reduced.

For example, an imaging device according to a tenth aspect of the present disclosure is the imaging device according to any one of the first to ninth aspects, in which D/√S ≥ 0.21 is satisfied.

Thus, it is possible to realize an imaging device in which noise is further reduced.

For example, an imaging device according to an eleventh aspect of the present disclosure includes pixels. Each of the pixels includes: a first electrode; a second electrode that is disposed to face the first electrode; a photoelectric conversion layer that is positioned between the first electrode and the second electrode, includes a donor semiconductor material and an acceptor semiconductor material, and generates signal charges; an intermediate layer that is positioned between the photoelectric conversion layer and the first electrode; and a charge accumulation region that is electrically connected to the first electrode and accumulates the signal charges. A shape of the first electrode in plan view is a square, and D/L ≥ 0.07 is satisfied, where D is a thickness of the intermediate layer, and L is a length of one side of the square in the shape of the first electrode in plan view.

Also with the configuration of the present aspect, as with the imaging device according to the first aspect, it is possible to realize an imaging device in which noise is reduced.

Hereafter, embodiments will be described with reference to the drawings.

The embodiments described below each represent a general or specific example. The values, shapes, constituent elements, arrangements of constituent elements, positions and connection configurations of constituent elements, steps, order of steps, and the like described in the following embodiments are examples, and do not limit the present disclosure. Among the constituent elements in the embodiments, constituent elements that are not described in the independent claims are optional constituent elements.

Each figure is not necessarily drawn strictly. In the figures, substantially the same configurations are denoted by the same numerals, and redundant descriptions thereof may be omitted or simplified.

In the present specification, terms that represent the relationships between elements such as "perpendicular", terms that represent the shapes of elements such as "rectangular", and numerical ranges not only have strict meanings but also have substantially equivalent meanings.

In the present specification, the terms "above" and "below" do not represent the upward direction (vertically above) and the downward direction (vertically below) in absolute spatial recognition, but are used as terms that are defined by a relative positional relationship based on the stacked order in a stacked configuration. The terms "above", "below", and the like are only used to specify relative arrangement of members and do not limit the position of an imaging device when the imaging device is used. The terms "above" and "below" are used, not only when two constituent elements are disposed with a space therebetween and another constituent element is present between the two constituent elements, but also when two constituent elements are disposed very close to each other and the two constituent elements are in close contact with each other.

In the present specification, unless otherwise noted, "plan view" refers to a view as seen in a direction perpendicular to the main surface of a photoelectric conversion layer. In the present specification, "main surface" refers to a surface perpendicular to the thickness direction, and a direction perpendicular to the main surface of a photoelectric conversion layer coincides with the thickness direction of each layer or each electrode of a photoelectric conversion element.

In the present specification, for convenience, the term "light" refers to electromagnetic radiation in general, including visible light, infrared radiation, and ultraviolet radiation.

### Embodiments

Hereafter, the present embodiment will be described.

### Photoelectric Conversion Element

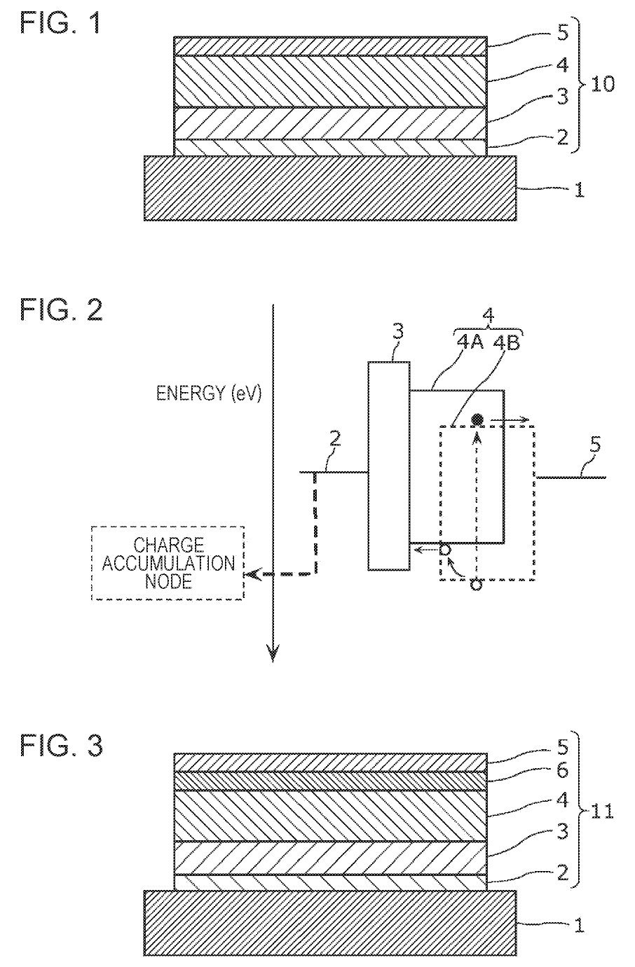

First, referring to FIG. 1, a photoelectric conversion element included in an imaging device according to the present embodiment will be described. The photoelectric conversion element according to the present embodiment is a charge-readout photoelectric conversion element. FIG. 1 is a schematic sectional view illustrating the configuration of a photoelectric conversion element 10 according to the present embodiment.

As illustrated in FIG. 1, the photoelectric conversion element 10 is supported by a support substrate 1, and includes an upper electrode 5 and a lower electrode 2 that are a pair of electrodes, a photoelectric conversion layer 4 between the upper electrode 5 and the lower electrode 2, and a charge blocking layer 3 positioned between the lower electrode 2 and the photoelectric conversion layer 4. In the present embodiment, the lower electrode 2 is an example of a first electrode, and the upper electrode 5 is an example of a second electrode. The charge blocking layer 3 is an example of an intermediate layer.

The photoelectric conversion element 10 is used, for example, in a disposition such that light that has passed through the upper electrode 5 enters the photoelectric conversion layer 4.

Hereafter, each constituent element of the photoelectric conversion element 10 according to the present embodiment will be described.

The support substrate 1 may be any substrate that is used to support a general photoelectric conversion element, and may be, for example, a glass substrate, a quartz substrate, a semiconductor substrate, a plastic substrate, or the like.

The lower electrode 2 and the upper electrode 5 are film-like electrodes that are disposed to face each other.

The lower electrode 2 collects signal charges generated by the photoelectric conversion layer 4. The lower electrode 2 is made of a metal, a metal nitride, a metal oxide, a polysilicon provided with electroconductivity, or the like. Examples of the metal include aluminum, copper, titanium, and tungsten. Examples of a method for providing a polysilicon with electroconductivity include doping the polysilicon with an impurity.

The upper electrode 5 is disposed to face the lower electrode 2 with the photoelectric conversion layer 4 therebetween. The upper electrode 5 is, for example, a transparent electrode made from a transparent electroconductive material. Examples of the material of the upper electrode 5 include transparent conducting oxide (TCO), indium tin oxide (ITO), indium zinc oxide (IZO), aluminum-doped zinc oxide (AZO), fluorine-doped tin oxide (FTO), SnO₂, and TiO₂. In accordance with a desirable transmittance, the upper electrode 5 may be made from TCO, a metal material such as aluminum (Al) or gold (Au), or a combination of such metal materials.

The materials of the lower electrode 2 and the upper electrode 5 are not limited to the electroconductive materials described above, and may be other materials. For example, the lower electrode 2 may be a transparent electrode.

Various methods are used to make the lower electrode 2 and the upper electrode 5 in accordance with the materials used. For example, when ITO is used, an electron beam method, a sputtering method, a resistance-heating deposition method, a chemical reaction method such as a sol-gel method, an indium-tin-oxide dispersion application method, or the like may be used. In this case, after an ITO film has been formed, UV-ozone treatment, plasma treatment, or the like may be additionally performed to make the lower electrode 2 and the upper electrode 5.

The photoelectric conversion layer 4 generates electrons and holes by absorbing light. Either the electrons or the holes are used as signal charges. That is, the photoelectric conversion layer 4 converts light into signal charges.

The photoelectric conversion layer 4 includes, for example, a donor semiconductor material and an acceptor semiconductor material. The photoelectric conversion layer 4 is made by using, for example, an organic semiconductor material. As a method of making the photoelectric conversion layer 4, it is possible to use, for example, a wet method such as an application method by spin coating or a dry method such as a vapor deposition method. A vapor deposition method is a method with which the material of a layer is evaporated and deposited on a substrate by heating the material in vacuum. It is also possible to make the charge blocking layer 3 by using a method similar to a method of making the photoelectric conversion layer 4.

The photoelectric conversion layer 4 is, for example, a mixture film having a bulk-hetero structure and including a donor semiconductor material such as a donor organic semiconductor material and an acceptor semiconductor material such as an acceptor organic semiconductor material. The photoelectric conversion layer 4 may have a stacked structure in which a layer of a donor semiconductor material and a layer of an acceptor semiconductor material are stacked.

The photoelectric conversion layer 4 can be easily formed as a thin film by including a donor organic semiconductor material and an acceptor organic semiconductor material. Hereafter, specific examples of a donor organic semiconductor material and an acceptor organic semiconductor material will be listed.

Examples of a donor organic semiconductor material include triarylamine compounds, benzidine compounds, pyrazoline compounds, styrylamine compounds, hydrazone compounds, triphenylmethane compounds, carbazole compounds, polysilane compounds, thiophene compounds, phthalocyanine compounds, naphthalocyanine compounds, subphthalocyanine compounds, cyanine compounds, merocyanine compounds, oxonol compounds, polyamine compounds, indole compounds, pyrrole compounds, pyrazole compounds, biphenyl compounds, terphenyl compounds, polyarylene compounds, fused aromatic carbocyclic compounds, and metal complexes including a nitrogen-containing heterocyclic compound as a ligand.

Examples of fused aromatic carbocyclic compounds include naphthalene derivatives, anthracene derivatives, phenanthrene derivatives, tetracene derivatives, pyrene derivatives, perylene derivatives, and fluoranthene derivatives.

Examples of an acceptor organic semiconductor material include fullerenes; fullerene derivatives; fused aromatic carbocyclic compounds; 5- to 7-membered heterocyclic compounds containing a nitrogen atom, an oxygen atom, and/or a sulfur atom; polyarylene compounds; fluorene compounds; cyclopentadiene compounds; silyl compounds; and metal complexes including a nitrogen-containing heterocyclic compound as a ligand.

Examples of fullerenes include C60 fullerene and C70 fullerene.

Examples of fullerene derivatives include phenyl C61 butyric acid methyl ester (PCBM) and indene-C60 bisadduct (ICBA).

Examples of 5- to 7-membered heterocyclic compounds containing a nitrogen atom, an oxygen atom, and/or a sulfur atom include: pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyrrolidine, pyrrolopyridine, thiadiazolopyridine, dibenzazepine, and tribenzazepine.

A donor organic semiconductor material and an acceptor organic semiconductor material are not limited to the above examples. Any low-molecular-weight or high-molecular-weight organic compound may be used as a donor organic semiconductor material or an acceptor organic semiconductor material of the photoelectric conversion layer 4, as long as the organic compound can be formed into a photoelectric conversion layer by using either a dry method or a wet method.

The photoelectric conversion layer 4 may include a material other than an organic semiconductor material as a donor semiconductor material or an acceptor semiconductor material. The photoelectric conversion layer 4 may include, as a semiconductor material, a silicon semiconductor, a compound semiconductor, quantum dots, a perovskite material, carbon nanotubes, or a mixture of two or more of these.

As described above, the photoelectric conversion element 10 according to the present embodiment includes the charge blocking layer 3 between the lower electrode 2 and the photoelectric conversion layer 4. The charge blocking layer 3 is, for example, in contact with the lower electrode 2 and the photoelectric conversion layer 4.

The charge blocking layer 3 includes, for example, a first semiconductor material. The first semiconductor material is, for example, an organic semiconductor material. The organic semiconductor material is, for example, the aforementioned donor organic semiconductor material or acceptor organic semiconductor material. The first semiconductor material of the charge blocking layer 3 is not limited to an organic semiconductor material, may be an oxide semiconductor, a nitride semiconductor, or the like, or may be a composite material of these. The material of the charge blocking layer 3 may be, for example, a metal oxide such as aluminum oxide.

The charge blocking layer 3 may have a structure in which layers are stacked. In this case, the materials of the layers may be the same, or may be different from each other.

The thickness of the charge blocking layer 3, which is set in accordance with the size of the lower electrode 2 as described below, is, for example, greater than or equal to 10 nm. In view of effective suppression of dark current and noise, the thickness of the charge blocking layer 3 may be greater than or equal to 100 nm, may be greater than or equal to 150 nm, or may be greater than or equal to 200 nm. In view of suppression of decrease of sensitivity, the thickness of the charge blocking layer 3 may be less than or equal to 1000 nm or may be less than or equal to 600 nm.

FIG. 2 is an exemplary energy band diagram of the photoelectric conversion element illustrated in FIG. 1. In FIG. 2, the energy band of each layer is represented by a rectangle. In FIG. 2, an electron is indicated by a black circle, a hole is indicated by a white circle, and some of the movements of electron and hole are schematically illustrated.

When irradiated with light, the photoelectric conversion layer 4 generates excitons therein. The generated excitons diffuse in the photoelectric conversion layer 4 and are separated into electrons and holes at the interface between an acceptor semiconductor material and a donor semiconductor material. The separated electrons and holes respectively move toward the lower electrode 2 or the upper electrode 5 in accordance with an electric field applied to the photoelectric conversion layer 4. When a voltage is applied between the upper electrode 5 and the lower electrode 2 so that the potential of the upper electrode 5 becomes higher than the potential of the lower electrode 2, electrons move toward the upper electrode 5 and holes move toward the lower electrode 2. When the photoelectric conversion element 10 is used for an imaging device, for example, holes are collected by the lower electrode 2 and are accumulated as signal charges in a charge accumulation node that is electrically connected to the lower electrode 2. The charge accumulation node is an example of a charge accumulation region that accumulates signal charges collected by the lower electrode 2. In this way, the photoelectric conversion layer 4 converts light into signal charges, and the lower electrode 2 collects signal charges generated by the photoelectric conversion layer 4. The upper electrode 5 collects charges whose polarity is opposite to that of signal charges. Hereafter, a case where holes moves toward the lower electrode 2 and holes are used as signal charges will be described. However, electrons may be used as signal charges. In this case, a voltage is applied between the upper electrode 5 and the lower electrode 2 so that the potential of the upper electrode 5 becomes lower than the potential of the lower electrode 2, holes move toward the upper electrode 5, and electrons move toward the lower electrode 2.

Here, the term "donor material" refers to a material that provides electrons, among the pairs of electrons and holes generated by absorbing light, to another material, and the term "acceptor material" refers to a material that accepts the electrons. In the present embodiment, the donor semiconductor material is a donor material, and the acceptor semiconductor material is an acceptor material. When two different organic semiconductor materials are used, which of these is a donor material and which of these is an acceptor material are determined by the relative positions of the energy levels of highest-occupied-molecular-orbital (HOMO) and lowest-unoccupied-molecular-orbital (LUMO) of the two organic semiconductor materials at the contact interface. In FIG. 2, in each rectangle representing the energy band, the upper end is the energy level of LUMO and the lower end is the energy level of HOMO. The energy difference between the vacuum level and the energy level of LUMO is called the electron affinity. The energy difference between the vacuum level and the energy level of HOMO is called the ionization potential. In FIG. 2, the lower the position, the greater the electron affinity and the ionization potential.

As illustrated in FIG. 2, among the two semiconductor materials included in the photoelectric conversion layer 4, a material whose energy level of LUMO is shallower, that is, the electron affinity is smaller, is a donor semiconductor material 4A that is a donor material. Among the two semiconductor materials included in the photoelectric conversion layer 4, a material whose energy level of LUMO is deeper, that is, the electron affinity is greater, is an acceptor semiconductor material 4B that is an acceptor material. In FIG. 2, the energy band of the donor semiconductor material 4A and the energy band of the acceptor semiconductor material 4B are illustrated to be displaced in the horizontal direction. However, this is for viewability, and does not mean that the donor semiconductor material 4A and the acceptor semiconductor material 4B are distributed separately in the thickness direction of the photoelectric conversion layer 4. The energy band of the acceptor semiconductor material 4B is represented by a broken-line rectangle. However, this is also for viewability, and it is not intended to discriminate a broken-line rectangle from a solid-line rectangle.

The ionization potential of the donor semiconductor material 4A is, for example, less than the ionization potential of the acceptor semiconductor material 4B.

The charge blocking layer 3 is configured to transport signal charges and to block charges whose polarity is opposite to that of signal charges. As illustrated in FIG. 2, when holes are used as signal charges, the electron affinity of the charge blocking layer 3 is, for example, less than or equal to the electron affinity of the acceptor semiconductor material 4B of the photoelectric conversion layer 4. Moreover, the electron affinity of the charge blocking layer 3 is less than the work function of the lower electrode 2. Thus, the charge blocking layer 3 suppresses injection of charges (to be specific, electrons) whose polarity is opposite to that of signal charges from the lower electrode 2 to the photoelectric conversion layer 4. As a result, it is possible to reduce noise signals due to dark current, which negatively influence the S/N ratio (signal-to-noise ratio). When the charge blocking layer 3 has a structure in which layers are stacked, the electron affinity of at least one of the layers is less than or equal to the electron affinity of the acceptor semiconductor material 4B of the photoelectric conversion layer 4 and is less than the work function of the lower electrode 2.

For example, the difference between the ionization potential of the charge blocking layer 3 and the ionization potential of the donor semiconductor material 4A is less than or equal to 1 eV. Thus, the efficiency of the lower electrode 2 in extracting signal charges (to be specific, holes) improves. When the charge blocking layer 3 has a structure in which layers are stacked, for example, the difference between the ionization potential of any of the layers and the ionization potential of the donor semiconductor material 4A is less than or equal to 1 eV.

In FIG. 2, the electron affinity and the ionization potential of the charge blocking layer 3 are, for example, the electron affinity and the ionization potential of a first semiconductor material included in the charge blocking layer 3.

When electrons are used as signal charges, in order to suppress injection of holes from the lower electrode 2 to the photoelectric conversion layer 4, the ionization potential of the charge blocking layer 3 is, for example, greater than or equal to the ionization potential of the donor semiconductor material 4A of the photoelectric conversion layer 4. When electrons are used as signal charges, the ionization potential of the charge blocking layer 3 is greater than the work function of the lower electrode 2.

When electrons are used as signal charges, the difference between the electron affinity of the charge blocking layer 3 and the electron affinity of the acceptor semiconductor material 4B is less than or equal to 1 eV. Thus, the efficiency of the lower electrode 2 in extracting signal charges (to be specific, electrons) improves.

### Another Example of Photoelectric Conversion Element

A photoelectric conversion element according to the present embodiment may further includes a charge blocking layer also between the upper electrode 5 and the photoelectric conversion layer 4. FIG. 3 is a schematic sectional view illustrating the configuration of another photoelectric conversion element 11 according to the present embodiment. As illustrated in FIG. 3, the photoelectric conversion element 11 further includes, in addition to the configuration of the photoelectric conversion element 10, a charge blocking layer 6 between the upper electrode 5 and the photoelectric conversion layer 4. The charge blocking layer 6 is, for example, in contact with the upper electrode 5 and the photoelectric conversion layer 4.

The charge blocking layer 6 includes, for example, a second semiconductor material. The second semiconductor material is, for example, an organic semiconductor material. The organic semiconductor material is, for example, the aforementioned donor organic semiconductor material or acceptor organic semiconductor material. The second semiconductor material of the charge blocking layer 6 is not limited to an organic semiconductor material, may be an oxide semiconductor, a nitride semiconductor, or the like, or may be a composite material of these. The material of the charge blocking layer 6 may be, for example, a metal oxide such as aluminum oxide. The charge blocking layer 6 may include the same material as the charge blocking layer 3.

The charge blocking layer 6 may have a structure in which layers are stacked. In this case, the materials of the layers may be the same, or may be different from each other.

The thickness of the charge blocking layer 6 is, for example, greater than or equal to 5 nm. In view of effective suppression of dark current and noise, the thickness of the charge blocking layer 6 may be greater than or equal to 10 nm, may be greater than or equal to 20 nm, or may be greater than or equal to 30 nm. In view of suppression of decrease of sensitivity, the thickness of the charge blocking layer 6 may be less than or equal to 500 nm or may be less than or equal to 300 nm.

The charge blocking layer 6 is configured to transport charges whose polarity is opposite to that of signal charges and to block signal charges. When holes are used as signal charges, the ionization potential of the charge blocking layer 6 is, for example, greater than or equal to the ionization potential of the donor semiconductor material 4A of the photoelectric conversion layer 4. The ionization potential of the charge blocking layer 6 is greater than the work function of the upper electrode 5. Thus, the charge blocking layer 6 suppresses injection of signal charges (to be specific, holes) from the upper electrode 5 to the photoelectric conversion layer 4. As a result, it is possible to reduce noise signals due to dark current, which negatively influence the S/N ratio. When the charge blocking layer 6 has a structure in which layers are stacked, the ionization potential of at least one of the layers is greater than or equal to the ionization potential of the donor semiconductor material 4A of the photoelectric conversion layer 4 and is greater than the work function of the upper electrode 5.

For example, the difference between the electron affinity of the charge blocking layer 6 and the electron affinity of the acceptor semiconductor material 4B is less than or equal to 1 eV. Thus, the efficiency in transporting charges (to be specific, electrons) whose polarity is opposite to that of signal charges to the upper electrode 5 improves. When the charge blocking layer 6 has a structure in which layers are stacked, for example, the difference between the electron affinity of any of the layers and the electron affinity of the acceptor semiconductor material 4B is less than or equal to 1 eV.

The electron affinity and the ionization potential of the charge blocking layer 6 are, for example, the electron affinity and the ionization potential of the second semiconductor material included in the charge blocking layer 6. The second semiconductor material included in the charge blocking layer 6 may be the same as the donor semiconductor material 4A included in the photoelectric conversion layer 4.

When electrons are used as signal charges, in order to suppress injection of electrons from the upper electrode 5 to the photoelectric conversion layer 4, the electron affinity of the charge blocking layer 6 is, for example, less than or equal to the electron affinity of the acceptor semiconductor material 4B of the photoelectric conversion layer 4. When electrons are used as signal charges, the electron affinity of the charge blocking layer 6 is less than the work function of the upper electrode 5.

When electrons are used as signal charges, the difference between the ionization potential of the charge blocking layer 6 and the ionization potential of the donor semiconductor material 4A is less than or equal to 1 eV. Thus, the efficiency in movement of charges (to be specific, holes) whose polarity is opposite to that of signal charges to the upper electrode 5 improves. When electrons are used as signal charges, the second semiconductor material included in the charge blocking layer 6 may be the same as the acceptor semiconductor material 4B included in the photoelectric conversion layer 4.

### Imaging Device

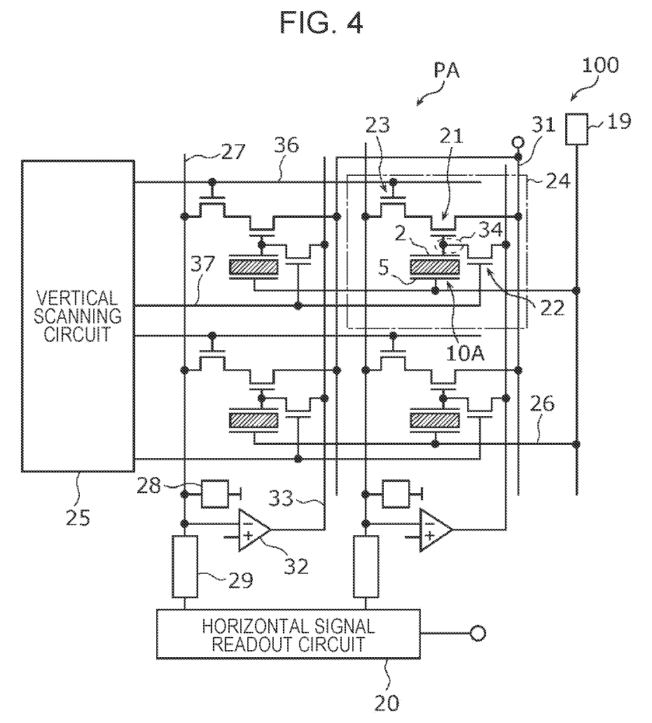

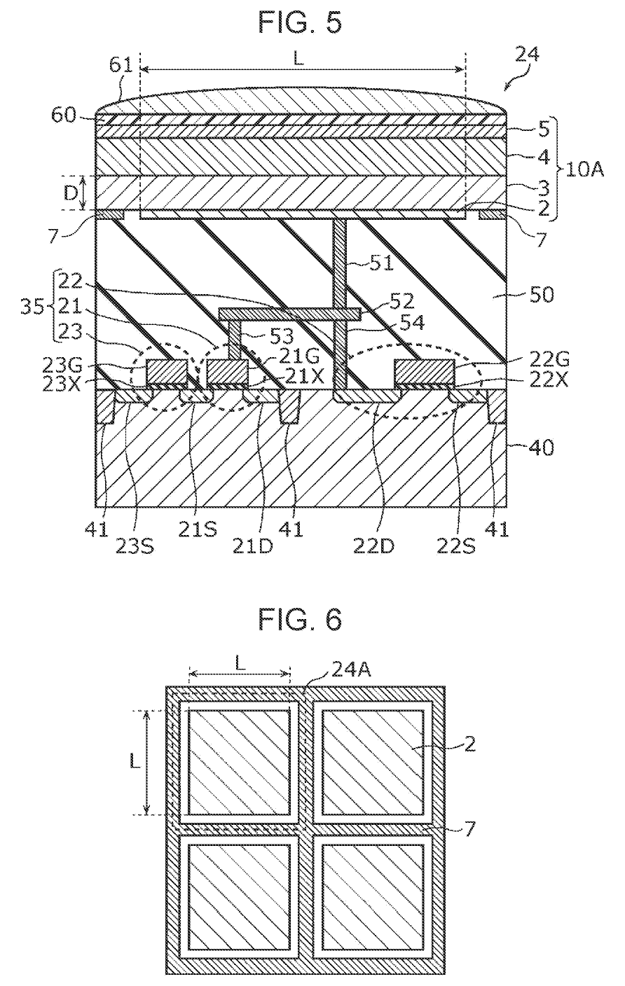

Next, referring to FIGS. 4 and 5, an imaging device according to the present embodiment will be described. FIG. 4 illustrates an example of the circuit configuration of an imaging device 100 including a photoelectric converter 10A using the photoelectric conversion element 10 illustrated in FIG. 1. FIG. 5 is a schematic sectional view illustrating the device structure of a pixel 24 of the imaging device 100 according to the present embodiment. In FIG. 4, illustration of an auxiliary electrode 7, which is illustrated in FIG. 5, is omitted.

As illustrated in FIGS. 4 and 5, the imaging device 100 according to the present embodiment includes: a semiconductor substrate 40; and pixels 24 each including a charge detection circuit 35 provided at the semiconductor substrate 40, the photoelectric converter 10A provided above the semiconductor substrate 40, and a charge accumulation node 34 electrically connected to the charge detection circuit 35 and the photoelectric converter 10A. The photoelectric converter 10A of each pixel 24 includes the aforementioned photoelectric conversion element 10. That is, each pixel 24 includes the lower electrode 2, the upper electrode 5, the photoelectric conversion layer 4, and the charge blocking layer 3. In the present embodiment, the charge accumulation node 34 is an example of a charge accumulation region. The photoelectric converter 10A may include the photoelectric conversion element 11. That is, each pixel 24 may further include the charge blocking layer 6 in addition to the configuration described above.

In the photoelectric converter 10A, the upper electrode 5, the photoelectric conversion layer 4, the charge blocking layer 3, and the lower electrode 2 are arranged in this order from the side from which light enters the imaging device 100. In the present embodiment, light that has passed through the upper electrode 5 enters the photoelectric conversion layer 4. In the present embodiment, the side from which light enters the imaging device 100 is opposite from the semiconductor substrate 40 side of the photoelectric converter 10A. In the present embodiment, the side from which light enters is the upper side.

The charge accumulation node 34 accumulates signal charges generated by the photoelectric converter 10A, and the charge detection circuit 35 detects signal charges accumulated in the charge accumulation node 34. The charge detection circuit 35, which is provided at the semiconductor substrate 40, may be provided on the semiconductor substrate 40, or may be directly provided in the semiconductor substrate 40.

As illustrated in FIG. 4, the imaging device 100 includes the pixels 24 and peripheral circuits. The imaging device 100 is, for example, an image sensor implemented in a one-chip integrated circuit, and includes a pixel array PA including the pixels 24 that are arranged two-dimensionally.

The pixels 24 are arranged on the semiconductor substrate 40 two dimensionally, that is, in the row direction and the column direction, to form a photosensitive region that is a pixel region. FIG. 4 illustrates an example in which the pixels 24 are arranged in a 2×2 matrix pattern. The arrangement of the pixels 24 is not limited to 2×2, and the number of rows and the number of columns of the pixels 24 are not particularly limited. In FIG. 4, for convenience of illustration, illustration of a circuit (for example, a pixel electrode control circuit) for individually setting the sensitivities of the pixels 24 is omitted. The imaging device 100 may be a line sensor. In this case, the pixels 24 may be arranged one-dimensionally. In the present specification, the term "row direction" and the term "column direction" respectively refer to a direction in which rows extend and a direction in which columns extend. That is, in FIG. 4, the vertical direction in the plane of the figure is the column direction, and the horizontal direction in the plane of the figure is the row direction.

As illustrated in FIGS. 4 and 5, each pixel 24 includes the photoelectric converter 10A, the charge detection circuit 35, and the charge accumulation node 34 electrically connected to the photoelectric converter 10A and the charge detection circuit 35. The charge detection circuit 35 includes an amplification transistor 21, a reset transistor 22, and an address transistor 23.

The photoelectric converter 10A includes the lower electrode 2, which is provided as a pixel electrode, and the upper electrode 5, which is provided as a counter electrode that faces the lower electrode 2. It is not necessary that the entirety of the photoelectric converter 10A be an element that is independent for each pixel 24, and a part of the photoelectric converter 10A may be shared by two or more pixels 24. A voltage for applying a predetermined bias voltage is supplied to the upper electrode 5 via a counter electrode signal line 26.

The lower electrode 2 is connected to a gate electrode 21G of the amplification transistor 21, and signal charges collected by the lower electrode 2 are accumulated in the charge accumulation node 34 positioned between the lower electrode 2 and the gate electrode 21G of the amplification transistor 21. For example, when signal charges are holes, the charge accumulation node 34 is electrically connected to the lower electrode 2 and accumulates holes, among the excitons generated by the photoelectric conversion layer 4.

A voltage in accordance with the quantity of signal charges accumulated in the charge accumulation node 34 is applied to the gate electrode 21G of the amplification transistor 21. The amplification transistor 21 amplifies the voltage, and the address transistor 23 selectively reads out the voltage as a signal voltage. The reset transistor 22 has a source/drain electrode connected to the lower electrode 2 via the charge accumulation node 34, and resets signal charges accumulated in the charge accumulation node 34. In other words, the reset transistor 22 resets the potential of the gate electrode 21G of the amplification transistor 21 and the lower electrode 2.

In order to selectively perform the above operation in the pixels 24, the imaging device 100 includes a power source wiring line 31, a vertical signal line 27, an address signal line 36, and a reset signal line 37. These lines are connected to each pixel 24. To be specific, the power source wiring line 31 is connected to the source/drain electrode of the amplification transistor 21, and the vertical signal line 27 is connected to the source/drain electrode of the address transistor 23. The address signal line 36 is connected to a gate electrode 23G of the address transistor 23. The reset signal line 37 is connected to a gate electrode 22G of the reset transistor 22.

The peripheral circuits include a voltage supply circuit 19, a vertical scanning circuit 25, a horizontal signal readout circuit 20, column signal processing circuits 29, load circuits 28, and differential amplifiers 32.

The voltage supply circuit 19 is electrically connected to the upper electrode 5 via the counter electrode signal line 26. By applying a voltage to the upper electrode 5, the voltage supply circuit 19 provides a potential difference between the upper electrode 5 and the lower electrode 2, that is, applies a voltage between the upper electrode 5 and the lower electrode 2. When the lower electrode 2 collects holes as signal charges, the voltage supply circuit 19 supplies, to the upper electrode 5, a voltage such that the potential of the upper electrode 5 becomes higher than the potential of the lower electrode 2. When the lower electrode 2 collects electrons as signal charges, the voltage supply circuit 19 supplies, to the upper electrode 5, a voltage such that the potential of the upper electrode 5 becomes lower than the potential of the lower electrode 2.

The sensitivity of the photoelectric converter 10A is controlled by switching a voltage suppled from the voltage supply circuit 19 to the upper electrode 5 between voltages that are different from each other. The voltage supply circuit 19 is not limited to a specific power source circuit, may be a circuit that generates a predetermined voltage, or may be a circuit that changes a voltage supplied from another power source to a predetermined voltage. The imaging device 100 need not include the voltage supply circuit 19. For example, a voltage may be supplied to the upper electrode 5 from an external power source.

The vertical scanning circuit 25 is connected to the address signal line 36 and the reset signal line 37, selects pixels 24 disposed in each row on a row-by-row basis, and performs readout of a signal voltage and resetting of the potential of the lower electrode 2. The power source wiring line 31, which is a source follower power source, supplies a predetermined power source voltage to each pixel 24. The horizontal signal readout circuit 20 is electrically connected to the column signal processing circuits 29. The column signal processing circuit 29 is electrically connected to the pixels 24 that are disposed in each column via the vertical signal line 27 corresponding to each column. The load circuit 28 is electrically connected to each vertical signal line 27. The load circuit 28 and the amplification transistor 21 form a source follower circuit.

The differential amplifiers 32 are provided to correspond to each column. An inverting input terminal of the differential amplifier 32 is connected to a corresponding vertical signal line 27. An output terminal of the differential amplifier 32 is connected to the pixel 24 via a feedback line 33 corresponding to each column.

The vertical scanning circuit 25 applies, via the address signal line 36, a row selection signal for controlling on and off of the address transistor 23 to the gate electrode 23G of the address transistor 23. Thus, a row to be read out is scanned and selected. A signal voltage is read out to the vertical signal line 27 from the pixel 24 in the selected row. The vertical scanning circuit 25 applies, via the reset signal line 37, a reset signal for controlling on and off of the reset transistor 22 to the gate electrode 22G of the reset transistor 22. Thus, a row of the pixel 24 to be reset is selected. The vertical signal line 27 transmits, to the column signal processing circuits 29, a signal voltage that has been read out from the pixel 24 selected by the vertical scanning circuit 25.

The column signal processing circuit 29 performs noise-reduction signal processing, which is typified by correlated double sampling, analog-to-digital conversion (AD conversion), and the like.

The horizontal signal readout circuit 20 sequentially reads out signals from the column signal processing circuits 29 to a horizontal common signal line.

The differential amplifier 32 is connected to the drain electrode of the reset transistor 22 via the feedback line 33. Accordingly, the differential amplifier 32 receives an output value of the address transistor 23 at the inverting input terminal. The differential amplifier 32 performs a feedback operation so that the gate potential of the amplification transistor 21 becomes a predetermined feedback voltage. At this time, the output voltage value of the differential amplifier 32 is, for example, 0 V or a positive voltage near 0 V. The term "feedback voltage" means the output voltage of the differential amplifier 32.

As illustrated in FIG. 5, the pixel 24 includes the semiconductor substrate 40, the charge detection circuit 35, the photoelectric converter 10A, the auxiliary electrode 7, and the charge accumulation node 34 (see FIG. 4).

The semiconductor substrate 40 may be an insulating substrate on which a semiconductor layer is provided on a surface thereof on a side on which a photosensitive region is formed, and may be, for example, a p-type silicon substrate. The semiconductor substrate 40 has impurity regions 21D, 21S, 22D, 22S, and 23S, and an element separation region 41 for electrical separation between the pixels 24. The impurity regions 21D, 21S, 22D, 22S, and 23S are, for example, n-type regions. Here, the element separation region 41 is provided between the impurity region 21D and the impurity region 22D. Thus, leakage of signal charges accumulated in the charge accumulation node 34 is suppressed. The element separation region 41 is formed, for example, by performing ion injection of an acceptor under a predetermined injection condition.

The impurity regions 21D, 21S, 22D, 22S, and 23S are, for example, dispersion regions formed in the semiconductor substrate 40. As illustrated in FIG. 5, the amplification transistor 21 includes the impurity region 21S, the impurity region 21D, and the gate electrode 21G. The impurity region 21S and the impurity region 21D respectively function as, for example, a source region and a drain region of the amplification transistor 21. A channel region of the amplification transistor 21 is formed between the impurity region 21S and the impurity region 21D.

Likewise, the address transistor 23 includes the impurity region 23S, the impurity region 21S, and the gate electrode 23G connected to the address signal line 36. In this example, the amplification transistor 21 and the address transistor 23 are electrically connected to each other by sharing the impurity region 21S. The impurity region 23S functions as, for example, a source region of the address transistor 23. The impurity region 23S has connection with the vertical signal line 27 illustrated in FIG. 4.

On the semiconductor substrate 40, an interlayer insulating layer 50 is stacked in such a way as to cover the amplification transistor 21, the address transistor 23, and the reset transistor 22. In FIG. 5, hatching that indicates the cross section of the interlayer insulating layer 50 is omitted for viewability.

A wiring layer (not shown) can be disposed in the interlayer insulating layer 50. The wiring layer is made from, for example, a metal such as copper, and can include, for example, wiring such as the aforementioned vertical signal line 27 in a part thereof. It is possible to set the number of insulating layers in the interlayer insulating layer 50 and the number of layers included in a wiring layer disposed in the interlayer insulating layer 50 to any appropriate number.

In the interlayer insulating layer 50, a contact plug 53 connected to the gate electrode 21G of the amplification transistor 21; a contact plug 54 connected to the impurity region 22D of the reset transistor 22; a contact plug 51 connected to the lower electrode 2; and wiring 52 that connects the contact plug 51, the contact plug 54, and the contact plug 53 are disposed. Thus, the impurity region 22D of the reset transistor 22 is electrically connected to the gate electrode 21G of the amplification transistor 21. In the configuration illustrated in FIG. 5, the contact plugs 51, 53, and 54, the wiring 52, the gate electrode 21G of the amplification transistor 21, and the impurity region 22D of the reset transistor 22 constitute at least a part of the charge accumulation node 34.

The charge detection circuit 35 detects signal charges collected by the lower electrode 2, and outputs a signal voltage. The charge detection circuit 35 includes the amplification transistor 21, the reset transistor 22, and the address transistor 23, and is formed in the semiconductor substrate 40.

The amplification transistor 21 is formed in the semiconductor substrate 40; and includes the impurity region 21D and the impurity region 21S that respectively function as a drain electrode and a source electrode, a gate insulating layer 21X formed on the semiconductor substrate 40, and the gate electrode 21G formed on the gate insulating layer 21X.

The reset transistor 22 is formed in the semiconductor substrate 40; and includes the impurity region 22D and the impurity region 22S that respectively function as a drain electrode and a source electrode, a gate insulating layer 22X formed on the semiconductor substrate 40, and the gate electrode 22G formed on the gate insulating layer 22X.

The address transistor 23 is formed in the semiconductor substrate 40; and includes the impurity regions 21S and 23S that respectively function as a drain electrode and a source electrode, a gate insulating layer 23X formed on the semiconductor substrate 40, and the gate electrode 23G formed on the gate insulating layer 23X. Through the impurity region 21S, the amplification transistor 21 and the address transistor 23 are connected in series.

The aforementioned photoelectric converter 10A is disposed on the interlayer insulating layer 50. In other words, in the present embodiment, the pixels 24 of the pixel array PA are formed on the semiconductor substrate 40. The pixels 24, which are arranged two-dimensionally on the semiconductor substrate 40, form a photosensitive region. The charge blocking layer 3, the photoelectric conversion layer 4, and the upper electrode 5 are formed, for example, across multiple pixels 24. On the other hand, the lower electrode 2 is provided in each pixel 24, and is electrically separated from the lower electrode 2 of an adjacent pixel 24 by being spatially separated from the lower electrode 2 of the adjacent pixel 24. As described above, the upper electrode 5 has connection with the counter electrode signal line 26 connected to the voltage supply circuit 19. Accordingly, it is possible to simultaneously apply a voltage of a desirable magnitude between multiple pixels 24 from the voltage supply circuit 19 via the counter electrode signal line 26. As long as it is possible to apply a voltage of a desirable magnitude from the voltage supply circuit 19, the upper electrode 5 may be separately provided in each pixel 24. Likewise, the photoelectric conversion layer 4 and the charge blocking layer 3 may be separately provided in each pixel 24.

The size of the lower electrode 2, such as the length L of one side of the lower electrode 2, and the thickness D of the charge blocking layer 3 in the photoelectric converter 10A will be described below. As illustrated in FIG. 5, the thickness D of the charge blocking layer 3 is also the shortest distance between the lower electrode 2 and the photoelectric conversion layer 4.

Here, the layout of the lower electrodes 2, which are pixel electrodes included in the imaging device 100, will be described. FIG. 6 is a plan view illustrating an exemplary electrode layout in the imaging device 100. FIG. 6 is a plan view of the lower electrodes 2 and the auxiliary electrode 7 seen through constituent elements on or above these electrodes. For ease of viewing, in FIG. 6, the lower electrodes 2 and the auxiliary electrode 7 are respectively illustrated with the same hatching as the lower electrode 2 and the auxiliary electrode 7 in the cross section of FIG. 5.

A pixel electrode region 24A illustrated in FIG. 6 is a region corresponding to one pixel 24 in plan view. In the example illustrated in FIG. 6, the lower electrodes 2 and the auxiliary electrode 7 are provided in the pixel electrode region 24A.

As illustrated in FIG. 6, the lower electrodes 2 are arranged, for example, in an array pattern. The auxiliary electrode 7 is disposed between adjacent lower electrodes 2 in plan view. In the illustrated example, the auxiliary electrode 7 surrounds the lower electrodes 2 in plan view. To be specific, the auxiliary electrode 7 is disposed in a grid pattern in plan view, and the lower electrodes2 is disposed in each grid. The auxiliary electrode 7 is, for example, integrally formed across pixels 24, and has the same potential in all pixels 24. However, the auxiliary electrode 7 may be provided so as to be separated for each pixel 24, or may be provided so as to be separated for pixel blocks each including two or more pixels 24 among the pixels.

In the example illustrated in FIG. 6, the shape of the lower electrode 2 in plan view is a square. However, the shape of the lower electrode 2 in plan view is not particularly limited. The shape of the lower electrode 2 in plan view may be a polygon such as a rectangle, a hexagon, or an octagon.

The auxiliary electrode 7 is, for example, connected to a voltage supply circuit, a ground, or the like (not shown) and is maintained at a predetermined potential. The auxiliary electrode 7 and the lower electrode 2 are electrically separated. The potential of the auxiliary electrode 7 is, for example, a fixed potential, but may be varied.

The auxiliary electrode 7 is provided in order to suppress accidental electrical contact. Between pixels that considerably differ in the quantity of charges accumulated in the charge accumulation nodes 34, the potential difference between the charge accumulation nodes 34 is large, the pixels influence each other, and the resolution and the like deteriorate. The auxiliary electrode 7 reduces mutual influence between adjacent pixels.

When the signal charges are holes, the potential of the auxiliary electrode 7 is set, for example, to be greater than the potential of the charge accumulation node 34 when the signal charges are reset. Thus, it is possible to suppress movement of signal charges to an adjacent pixel and to extract signal charges that are generated near the auxiliary electrode 7 with high efficiency, and the sensitivity improves. The potential of the auxiliary electrode 7 may be set to be less than the potential of the charge accumulation node 34 when signal charges are reset. Also in this case, signal charges are collected by the auxiliary electrode 7, and movement of signal charges to an adjacent pixel can be suppressed.

The auxiliary electrode 7 is made of a metal, a metal nitride, a metal oxide, a polysilicon provided with electroconductivity, or the like. Examples of the metal include aluminum, copper, titanium, and tungsten. Examples of a method for providing a polysilicon with electroconductivity include doping the polysilicon with an impurity. The auxiliary electrode 7 may be made of the same material as the lower electrode 2.

Referring back to FIG. 5, a color filter 60 is formed above the photoelectric converter 10A, and a microlens 61 is formed above the color filter 60. The color filter 60 is formed, for example, as an on-chip color filter by patterning, and a photosensitive resin or the like in which a dye or a pigment is dispersed is used as the material of the color filter 60. The microlens 61 is formed, for example, as an on-chip microlens, and an ultraviolet sensitive material or the like is used as the material of the microlens 61.

It is possible to use a general semiconductor manufacturing process to manufacture the imaging device 100. In particular, when a silicon substrate is to be used as the semiconductor substrate 40, it is possible to manufacture the imaging device 100 by using various silicon semiconductor processes.

The imaging device 100 may operate, for example, by using a rolling shutter method with which signals are read out by exposing the pixels 24 to light sequentially from pixel column to pixel column, or may operate by using a global shutter method in which the exposure periods of the pixels 24 are uniform. When the imaging device 100 operates by using a rolling shutter method, during imaging, for example, the voltage supply circuit 19 continues to apply, to the upper electrode 5, a voltage such that the photoelectric converter 10A has sensitivity, and an operation of reading out signal charges is performed sequentially from pixel column to pixel column. When the imaging device 100 operates by using a global shutter method, for example, the voltage supply circuit 19 supplies, to the upper electrode 5, a voltage for performing imaging with desirable sensitivity in the exposure period, and supplies, to the upper electrode 5, a voltage such that the photoelectric converter 10A does not have sensitivity in the non-exposure period. Therefore, the photoelectric conversion efficiency of the pixels 24 in the exposure period is different from the photoelectric conversion efficiency of the pixels 24 in the non-exposure period, and, to be specific, is higher than the photoelectric conversion efficiency of the pixels 24 in the non-exposure period. The exposure period is a period for accumulating signal charges in the charge accumulation node 34. In the non-exposure period, an operation of reading out signal charges accumulated in the charge accumulation node 34 in the exposure period is sequentially performed from pixel column to pixel column. A readout operation of the imaging device 100 is not limited to such an operation, and any readout operation of known imaging devices can be used.

### Thickness of Charge Blocking Layer and Size of Lower Electrode

With the imaging device 100 according to the present embodiment, it is possible to reduce noise because the thickness of the charge blocking layer 3 and the size of the lower electrode 2 have a predetermined relationship.

First, the reason why noise is generated in the imaging device 100 will be described.

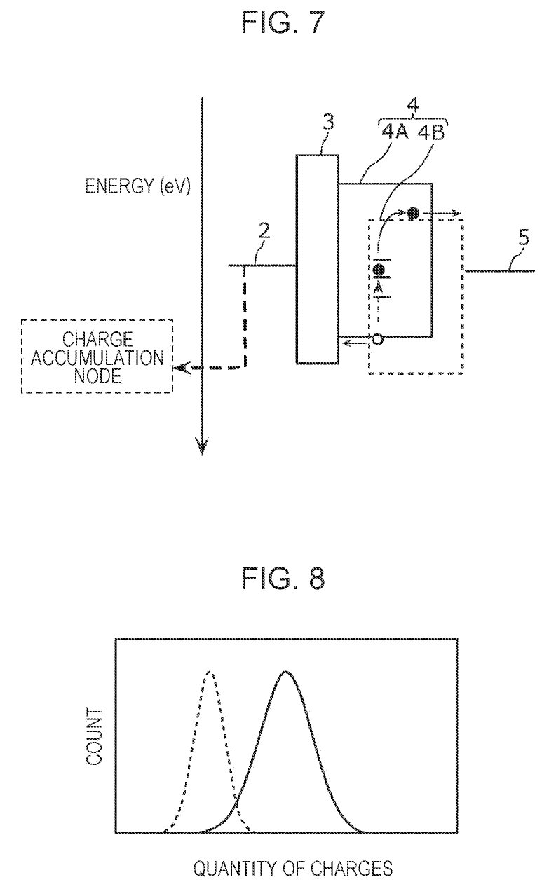

FIG. 7 is a view for illustrating a case where an intermediate level is generated in the photoelectric conversion element 10 having the energy band configuration illustrated in FIG. 2. An intermediate level tends to be generated in the vicinity of the interface between the charge blocking layer 3 and the photoelectric conversion layer 4 due to the influence of film-forming conditions and polarizing actions between materials. As illustrated in FIG. 7, an intermediate level is generated, for example, in the acceptor semiconductor material 4B included in the photoelectric conversion layer 4.

Compared with the energy difference between the energy level of HOMO of the donor semiconductor material 4A and the energy level of LUMO of the acceptor semiconductor material 4B included in the photoelectric conversion layer 4, the energy difference between the energy level of HOMO of the donor semiconductor material 4A and the intermediate level is small. Therefore, due to the presence of the intermediate level, even with thermal energy, which is usually small compared with optical energy, electrons and holes are easy generated in the photoelectric conversion layer 4 via the intermediate level.

When signal charges are holes, electrons generated by thermal energy are extracted to the upper electrode 5 by way of the acceptor semiconductor material 4B. Holes generated by thermal energy are extracted to the lower electrode 2 by way of the donor semiconductor material 4A and the charge blocking layer 3. Holes extracted to the lower electrode 2 are accumulated in the charge accumulation node 34, dispersion increases in accordance with the average value of the quantity of charges accumulated in the charge accumulation node 34 and becomes a factor in generation of noise. This noise is a type of shot noise, and is random noise that is proportional to the square root of the average value of the quantity of charges. Hereafter, among charges generated via an intermediate level, charges having the same polarity as signal charges may be referred to as noise charges.

FIG. 8 is a graph illustrating examples of the distribution of the quantity of charges accumulated in the charge accumulation node 34. In FIG. 8, the horizontal axis represents the quantity of charges accumulated in the charge accumulation node 34. In FIG. 8, the vertical axis represents one of the followings: the number of charge accumulation nodes 34 in which charges in the quantity represented by the horizontal axis are accumulated when the charges are accumulated in the charge accumulation nodes 34 under the same conditions; and the number of times charges in the quantity represented by the horizontal axis are accumulated in the charge accumulation node 34 when charges are accumulated in the charge accumulation node 34 multiple times at regular intervals under the same conditions.

In FIG. 8, the solid line exemplarily illustrates the distribution when the quantity of charges accumulated in the charge accumulation node 34 is large. In FIG. 8, the broken line exemplarily illustrates the distribution when the quantity of charges accumulated in the charge accumulation node 34 is small. Here, because dispersion of the quantity of charges is proportional to the square root of the average value of the quantity of charges as described above, the distribution becomes narrower as the average value represented by the horizontal axis decreases. Thus, noise is reduced.

Because an intermediate level tends to be generated in the vicinity of the interface between the charge blocking layer 3 and the photoelectric conversion layer 4, the quantity of noise charges generated via the intermediate level depends on the size of the interface between the charge blocking layer 3 and the photoelectric conversion layer 4. Therefore, in each pixel 24, the quantity of noise charges generated via the intermediate level depends on the size of an effective region of the photoelectric conversion layer 4 and the charge blocking layer 3 from which charges can be extracted by the lower electrode 2. In each pixel 24, because the photoelectric conversion layer 4 and the charge blocking layer 3 are stacked on the entire surface of the lower electrode 2, the size of the effective region of the photoelectric conversion layer 4 and the charge blocking layer 3 is determined by the size of the lower electrode 2 in plan view. For example, in each pixel 24, as the area of the lower electrode 2 in plan view increases, the quantity of noise charges accumulated in the charge accumulation node 34 tends to increase more easily, and the dispersion is represented by a physical quantity that is calculated based on the square root of the quantity of noise charges.

Some of noise charges generated via the intermediate level recombine with charges whose polarity is opposite to that of noise charges and become inactive. At this time, as the distance over which noise charges are extracted to the lower electrode 2 increases, that is, as the thickness of the charge blocking layer 3 increases, noise charges more easily combine with charges whose polarity is opposite to that of noise charges, and, as a result, the quantity of noise charges accumulated in the charge accumulation node 34 decreases.

In this way, dispersion of the quantity of noise charges that are generated via an intermediate level and accumulated in the charge accumulation node 34 depends on the area of the lower electrode 2 in plan view and the thickness of the charge blocking layer 3. Therefore, when the ratio of the thickness of the charge blocking layer 3 to the area of the lower electrode 2 in plan view satisfies a predetermined condition, it is possible to realize an imaging device 100 in which noise is reduced. To be specific, it is possible to realize an imaging device 100 in which noise is reduced when D/√S ≥ 0.07 is satisfied in the imaging device 100, where D is the thickness of the charge blocking layer 3 and S is the area of the lower electrode 2 in plan view. That is, in the imaging device 100, the thickness D of the charge blocking layer 3 is greater than or equal to 7% of the square root of the area S of the lower electrode 2. In view of further reduction of noise, D/√S ≥ 0.14 may be satisfied or D/√S ≥ 0.21 may be satisfied in the imaging device 100. In the example illustrated in FIG. 6, because the shape of the lower electrode 2 in plan view is a square, D/L ≥ 0.07 is satisfied in the imaging device 100, where L is the length of one side of the square in the shape of the lower electrode 2 in plan view. In view of further reduction of noise, D/L ≥ 0.14 may be satisfied or D/L ≥ 0.21 may be satisfied in the imaging device 100.

In view of suppressing decrease of the field intensity on the photoelectric converter 10A and maintaining the sensitivity of the photoelectric converter 10A, the upper limit value of D/√S and D/L may be 0.50 or may be 0.25. That is, D/√S ≤ 0.50 and D/L ≤ 0.50 may be satisfied, or D/√S ≤ 0.25 and D/L ≤ 0.25 may be satisfied.

The influence of the presence of the auxiliary electrode 7 on noise is small. As described above, when signal charges are holes, for example, the potential of the auxiliary electrode 7 is set to be greater than the potential of the charge accumulation node 34 in which signal charges have been reset. That is, most of charges generated in the photoelectric converter 10A are extracted to the lower electrode 2 irrespective of the presence or absence of the auxiliary electrode 7. Thus, the same applies to noise charges generated via an intermediate level, and the influence of the presence of the auxiliary electrode 7 on noise is small.

Next, referring to FIG. 4, the saturation signal quantity and the dynamic range, which is the ratio of the saturation signal quantity to noise, of the imaging device 100 will be described. Here, a case where holes are used as signal charges will be described.

In FIG. 4, as described above, holes generated in the photoelectric converter 10A are accumulated in the charge accumulation node 34. As holes are accumulated, the potential of the charge accumulation node 34 rises. That is, in this case, the maximum potential corresponding to the quantity of charges that the charge accumulation node 34 can hold is the saturation signal quantity in the imaging device 100. In general, a voltage amplitude of about 3 V in the charge accumulation node 34, which corresponds to the gate voltage of the amplification transistor 21, is allowed. In this case, for example, when noise of 6 e⁻ is generated in an imaging device whose conversion gain is 50 μV/e⁻, a dynamic range of 80 dB, which is equivalent to that of human eye, can be reliably obtained. With the imaging device 100 according to the present embodiment, because noise charges generated via an intermediate level do not easily accumulate in the charge accumulation node 34 as described above, noise is reduced, and it is possible to realize a wide dynamic range.

### EXAMPLES

Hereafter, an imaging device according to the present disclosure will be specifically described by using Examples. However, the present disclosure is not limited at all to the following Examples. To be specific, imaging devices according to the present disclosure and imaging devices for characteristics comparison were made, and noise was measured.

### Making of Imaging Device

Imaging devices according to Examples and Comparative Example were made.

### Comparative Example 1

First, with the device structure of the pixel 24 and the layout of the lower electrode 2 illustrated in FIGS. 5 and 6, the interlayer insulating layer 50 was stacked on the semiconductor substrate 40 on which the charge detection circuit 35 had been formed, and the lower electrode 2 connected to the charge detection circuit 35 via the charge accumulation node 34 was formed from TiN on the interlayer insulating layer 50. At this time, the length L of one side of the square in the shape of the lower electrode 2 in plan view was 2.1 μm. Therefore, the area S of the lower electrode 2 in plan view was 4.41 μm².

Next, the charge blocking layer 3 was formed by depositing 9,9'-[1,1'-Biphenyl]-4,4'-diylbis[3,6-bis (1,1-dimethylethyl)]-9H-carbazole on the lower electrode 2 by vacuum vapor deposition. The thickness D of the charge blocking layer obtained at this time was 50 nm.

Next, the photoelectric conversion layer 4 was formed on the charge blocking layer 3 by vacuum-vapor co-depositing subphthalocyanine, which is a donor semiconductor material, and fullerene C60, which is an acceptor semiconductor material, as materials of the photoelectric conversion layer 4. As the subphthalocyanine, subphthalocyanine that had boron (B) as the central metal and in which a chloride ion was coordinated to B as a ligand was used.

Next, an imaging device according to Comparative Example 1 was obtained by, after forming an ITO film as the upper electrode 5 on the photoelectric conversion layer 4 by sputtering, further forming an Al₂O₃ film as a sealing film on the upper electrode 5 by atomic layer deposition. In the imaging device according to Comparative Example 1, D/L = D/√S = 0.024.

### Example 1

Except that the thickness D of the charge blocking layer 3 was 150 nm, steps similar to those of Comparative Example 1 were performed, and an imaging device according to Example 1 was obtained. In the imaging device according to Example 1, D/L = D/√S = 0.071.

### Example 2

Except that the thickness D of the charge blocking layer 3 was 300 nm, steps similar to those of Comparative Example 1 were performed, and an imaging device according to Example 2 was obtained. In the imaging device according to Example 2, D/L = D/√S = 0.14.

### Example 3

Except that the thickness D of the charge blocking layer 3 was 450 nm, steps similar to those of Comparative Example 1 were performed, and an imaging device according to Example 3 was obtained. In the imaging device according to Example 3, D/L = D/√S = 0.21.

### Measurement of Random Noise

Regarding the imaging devices according to Examples and Comparative Example, in order to evaluate noise, an output detected by the charge detection circuit 35 of each pixel 24 was acquired. To be specific, in a state in which light did not enter the imaging device, when a predetermined time elapsed after the potential of the charge accumulation node 34 of each pixel 24 had been reset, an output detected by the charge detection circuit 35 based on the quantity of charges accumulated in the charge accumulation node 34 was acquired. At this time, a voltage of -1 V relative to the potential of the lower electrode 2 was applied between the lower electrode 2 and the upper electrode 5. That is, a voltage such that the potential of the upper electrode 5 became lower than the potential of the lower electrode 2 was applied between the lower electrode 2 and the upper electrode 5. Then, the standard deviation of outputs from the pixels 24 was calculated as random noise.

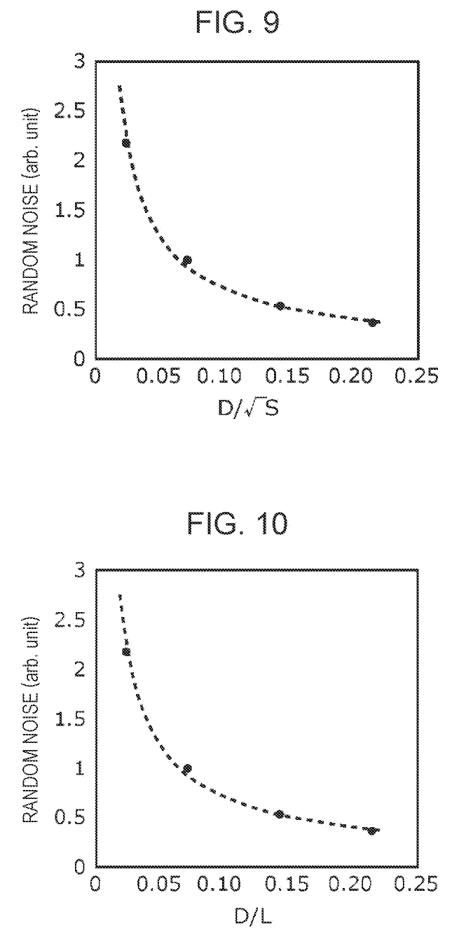

FIG. 9 is a graph illustrating the relationship between D/√S and random noise in the imaging devices according to Examples and Comparative Example. FIG. 10 is a graph illustrating the relationship between D/L and random noise in the imaging devices according to Examples and Comparative Example. In FIGS. 9 and 10, the vertical axis represents random noise. The value of random noise along the vertical axis is normalized in such a way that the value of random noise when the dynamic range is 80 dB, which is equivalent to that of human eye, is 1 with respect to the saturated signal quantity of the imaging devices according to Examples and Comparative Example. In this case, the dynamic range is 20log₁₀(saturated signal quantity/random noise). In FIG. 9, the horizontal axis represents D/√S, and in FIG. 10, the horizontal axis represents D/L.

As illustrated in FIGS. 9 and 10, it can be seen that, in an imaging device in which D/√S ≥ 0.07 and D/L ≥ 0.07 are satisfied as in imaging devices according to Examples 1 to 3, because the random noise of the imaging device is reduced and the random noise is less than or equal to 1, a wide dynamic range of greater than or equal to 80 dB, which is equivalent to that of human eye, can be realized.

In this way, with an imaging device according to the present disclosure, because D/√S ≥ 0.07 and D/L ≥ 0.07 are satisfied as in the imaging devices according to Examples 1 o 3, an imaging device in which noise is reduced is realized. This is presumably because, even when noise charges are generated via an intermediate level, the noise charges are not easily accumulated in the charge accumulation node 34.

Heretofore, an imaging device according to the present disclosure has been described based on embodiments and Examples. However, the present disclosure is not limited to these embodiments and Examples. Without departing from the gist of the present disclosure, the scope of the present disclosure includes configurations in which various modifications that a person having ordinary skill in the art can conceive are made on the embodiments and Examples and other configurations that are constructed by combining some of the constituent elements of the embodiments and Examples.

An imaging device according to the present disclosure is applicable to various camera systems, such as a medical camera, a monitor camera, a car-mounted camera, a distance measurement camera, a microscope camera, a drone camera, and a robot camera, and sensor systems.

What is claimed is:

1. An imaging device comprising:
pixels, wherein each of the pixels includes a first electrode, a second electrode that is disposed to face the first electrode,
a photoelectric conversion layer that is positioned between the first electrode and the second electrode, includes a donor semiconductor material and an acceptor semiconductor material, and generates signal charges, an intermediate layer that is positioned between the photoelectric conversion layer and the first electrode, and a charge accumulation region that is electrically connected to the first electrode and accumulates the signal charges, and
wherein D/√S ≥ 0.07 is satisfied, where D is a thickness of the intermediate layer, and S is an area of the first electrode in plan view.

2. The imaging device according to claim 1,
wherein the thickness of the intermediate layer is greater than or equal to 10 nm.

3. The imaging device according to claim 1,
wherein the signal charges are holes, wherein the intermediate layer includes a first semiconductor material, and
wherein a difference between an ionization potential of the first semiconductor material included in the intermediate layer and an ionization potential of the donor semiconductor material included in the photoelectric conversion layer is less than or equal to 1 eV.

4. The imaging device according to claim 1,
wherein the signal charge are electrons, wherein the intermediate layer includes a first semiconductor material, and wherein a difference between an electron affinity of the first semiconductor material included in the intermediate layer and an electron affinity of the acceptor semiconductor material included in the photoelectric conversion layer is less than or equal to 1 eV.

5. The imaging device according to claim 1,
wherein each of the pixels further includes a charge blocking layer that is positioned between the second electrode and the photoelectric conversion layer.

6. The imaging device according to claim 5,
wherein a thickness of the charge blocking layer is greater than or equal to 5 nm.

7. The imaging device according to claim 5, wherein the signal charges are holes, wherein the charge blocking layer includes a second semiconductor material, and wherein a difference between an electron affinity of the second semiconductor material included in the charge blocking layer and an electron affinity of the acceptor semiconductor material included in the photoelectric conversion layer is less than or equal to 1 eV.

8. The imaging device according to claim 5, wherein the signal charges are electrons, wherein the charge blocking layer includes a second semiconductor material, and wherein a difference between an ionization potential of the second semiconductor material included in the charge blocking layer and an ionization potential of the donor semiconductor material included in the photoelectric conversion layer is less than or equal to 1 eV.

9. The imaging device according to claim 1, wherein D/√S ≥ 0.14 is satisfied.

10. The imaging device according to claim 1, wherein D/√S ≥ 0.21 is satisfied.

11. An imaging device comprising:
pixels, wherein each of the pixels includes a first electrode, a second electrode that is disposed to face the first electrode, a photoelectric conversion layer that is positioned between the first electrode and the second electrode, includes a donor semiconductor material and an acceptor semiconductor material, and generates signal charges, an intermediate layer that is positioned between the photoelectric conversion layer and the first electrode, and a charge accumulation region that is electrically connected to the first electrode and accumulates the signal charges, wherein a shape of the first electrode in plan view is a square, and wherein 0D/L ≥ .07 is satisfied, where D is a thickness of the intermediate layer, and L is a length of one side of the square in the shape of the first electrode in plan view.
